(19) United States
(12) Patent Application Publication
(10) Pub. No.: US 2026/0068321 A1
(43) Pub. Date: Mar. 5, 2026

(54) ELECTRO-OPTICAL DEVICE AND ELECTRONIC INSTRUMENT

(71) Applicant: SEIKO EPSON CORPORATION, Tokyo (JP)

(72) Inventor: Hiroyuki OIKAWA, Chitose-shi (JP)

(73) Assignee: SEIKO EPSON CORPORATION, Tokyo (JP)

(21) Appl. No.: 19/312,304

(22) Filed: Aug. 28, 2025

(30) Foreign Application Priority Data
Aug. 29, 2024 (JP) 2024-147332

(51) Int. Cl. H10D 86/40

(52) U.S. Cl. CPC H10D 86/451; H10D 86/441

(57) ABSTRACT

An electro-optical device includes a substrate; a pixel electrode; a laminate including multiple insulating layers disposed between the substrate and the pixel electrode; a pixel electrode contact provided in the laminate and coupled to the pixel electrode; a transistor provided in the laminate; and a capacitance element provided in the laminate and including a first capacitance electrode, a dielectric, and a second capacitance electrode, the laminate is provided with a hole portion, the capacitance element includes a trench portion provided in the hole portion, and the trench portion overlaps with the pixel electrode contact in a plan view.

The present application is based on, and claims priority from JP Application Serial Number 2024-147332, filed Aug. 29, 2024, the disclosure of which is hereby incorporated by reference herein in its entirety.

### BACKGROUND

### 1. Technical Field

The present disclosure relates to an electro-optical device and an electronic instrument.

### 2. Related Art

An electronic instrument such as a projector uses, for example, an electro-optical device such as a liquid crystal display device capable of changing optical characteristics on a pixel basis.

JP-A-2019-078825 discloses an electro-optical device having a light blocking region and a light transmitting region. The electro-optical device has storage capacitance and pixel electrodes. The storage capacitance is provided in the light blocking region, and the pixel electrodes are provided in the light transmitting region. One of a pair of capacitance electrodes provided in the storage capacitance is electrically coupled to the corresponding one of the pixel electrodes via a contact hole. The storage capacitance is disposed along a recess provided in the light blocking region to increase the capacitance.

JP-A-2019-078825 is an example of the related art.

Capacitance elements described in JP-A-2019-078825 are provided in the light blocking region different from an opening region in which the pixel electrodes are provided. In the technology described in JP-A-2019-078825, however, reducing the light blocking region to achieve a high opening ratio disadvantageously causes deterioration of the expected effect of increasing the capacitance even when the capacitance electrodes are each formed along the recess provided in the light blocking region.

### SUMMARY

An electro-optical device according to an aspect of the present disclosure includes: a substrate; a pixel electrode; a laminate including multiple insulating layers disposed between the substrate and the pixel electrode; a pixel electrode contact provided in the laminate and coupled to the pixel electrode; a transistor provided in the laminate; and a capacitance element provided in the laminate and including a first capacitance electrode, a dielectric, and a second capacitance electrode, the laminate is provided with a hole portion, the capacitance element includes a trench portion provided in the hole portion, and the trench portion overlaps with the pixel electrode contact in a plan view.

### BRIEF DESCRIPTION OF THE DRAWINGS

FIG. 1 is a plan view of an electro-optical device according to an embodiment.

FIG. 2 is a cross-sectional view of the electro-optical device taken along the line A-A shown in FIG. 1.

FIG. 3 is an equivalent circuit diagram showing the electrical configuration of an element substrate in FIG. 1.

FIG. 4 is a plan view showing a portion of the element substrate in a display region in FIG. 2.

FIG. 5 is a cross-sectional view taken along the line A1-A1 in FIG. 4.

FIG. 6 is a cross-sectional view taken along the line A2-A2 in FIG. 4.

FIG. 7 is a plan view showing a transistor in FIG. 5.

FIG. 8 shows a planar arrangement of a trench portion and a pixel electrode shown in FIG. 5.

FIG. 9 shows a planar arrangement of a capacitance element shown in FIG. 5.

FIG. 10 is a plan view corresponding to the line B1-B1 in FIG. 5.

FIG. 11 is a plan view corresponding to the line B2-B2 in FIG. 5.

FIG. 12 is a cross-sectional view taken along the line A3-A3 in FIG. 4.

FIG. 13 is a plan view corresponding to the line B3-B3 in FIG. 5.

FIG. 14 is a plan view corresponding to the line B4-B4 in FIG. 5.

FIG. 15 shows an example of a method for manufacturing the capacitance element.

FIG. 16 shows an example of the method for manufacturing the capacitance element.

FIG. 17 shows an example of the method for manufacturing the capacitance element.

FIG. 18 shows an example of the method for manufacturing the capacitance element.

FIG. 19 shows an example of the method for manufacturing the capacitance element.

FIG. 20 shows an example of the method for manufacturing the capacitance element.

FIG. 21 is a perspective view showing a personal computer as an example of an electronic instrument.

FIG. 22 is a plan view showing a smartphone as an example of the electronic instrument.

FIG. 23 is a diagrammatic view showing a projector as an example of the electronic instrument.

### DESCRIPTION OF EMBODIMENTS

A preferable embodiment according to the present disclosure will be described below with reference to the accompanying drawings. Note in the drawings that the dimensions or scale of each portion differ from the actual values as appropriate, and some portions are diagrammatically shown to facilitate understanding thereof. The scope of the present disclosure is not limited to the embodiment unless there is a description that particularly limits the present disclosure in the following description.

### 1. Electro-Optical Device

### 1A. Basic Configuration

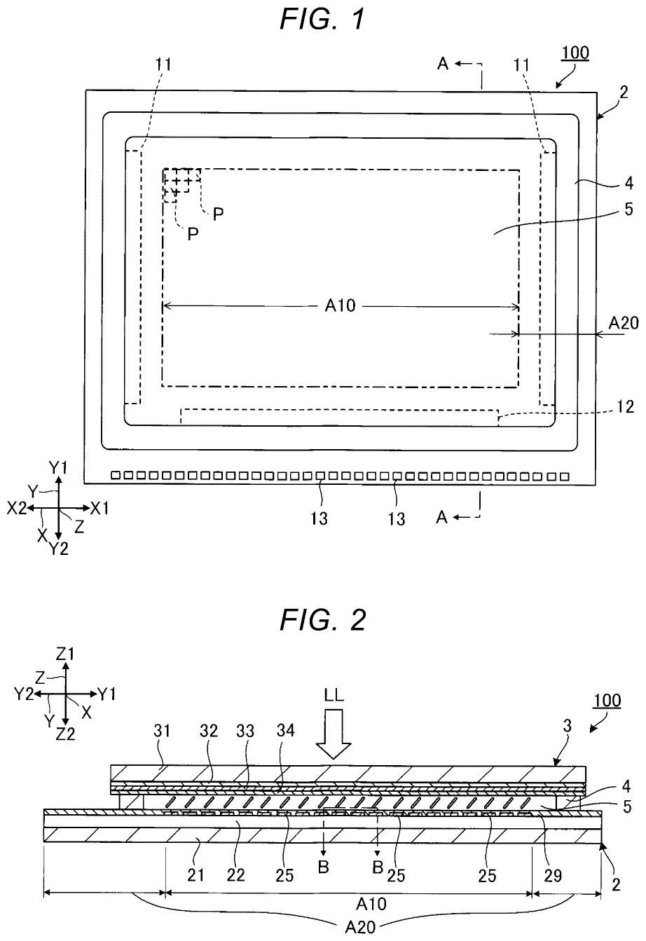

FIG. 1 is a plan view of an electro-optical device 100 according to an embodiment. FIG. 2 is a cross-sectional view of the electro-optical device 100 taken along the line A-A shown in FIG. 1. Note that FIG. 1 does not show a counter substrate 3. The following description will be made by using an X-axis, a Y-axis, and a Z-axis orthogonal to each other as appropriate for convenience of the description. One direction along the X-axis is referred to as an X1 direction, and the direction opposite the X1 direction is referred to as an X2 direction. Similarly, one direction along the Y-axis is referred to as a Y1 direction, and the direction opposite the Y1 direction is referred to as a Y2 direction. One direction along the Z-axis is referred to as a Z1 direction, and the direction opposite the Z1 direction is referred to as a Z2 direction.

In the present specification, “an element β on an element α” means that the element β is located above the element α. Therefore, the phrase “an element β on an element α” includes not only a case where the element β is in direct contact with the element α but also a case where the element α and the element β are separate from each other. Furthermore, “electrical coupling” between the element α and the element β includes not only a configuration in which the element α and the element β are directly joined to each other so as to be electrically conductive to each other, but also a configuration in which the element α and the element β are indirectly electrically conductive to each other via another electrical conductor.

The electro-optical device 100 shown in FIGS. 1 and 2 is a transmissive electro-optical device driven in an active matrix mode. The electro-optical device 100 includes an element substrate 2, a counter substrate 3, a frame-shaped sealing member 4, and a liquid crystal layer 5. The element substrate 2, the liquid crystal layer 5, and the counter substrate 3 are arranged in this order in the Z1 direction, as shown in FIG. 2. Note that the view in the Z1 direction or the Z2 direction, which is the direction in which the elements described above are layered on each other, is referred to as a “plan view”. The electro-optical device 100 shown in FIG. 1 has a quadrangular shape in the plan view, and may instead have a polygonal shape other than a quadrangular shape or a circular shape.

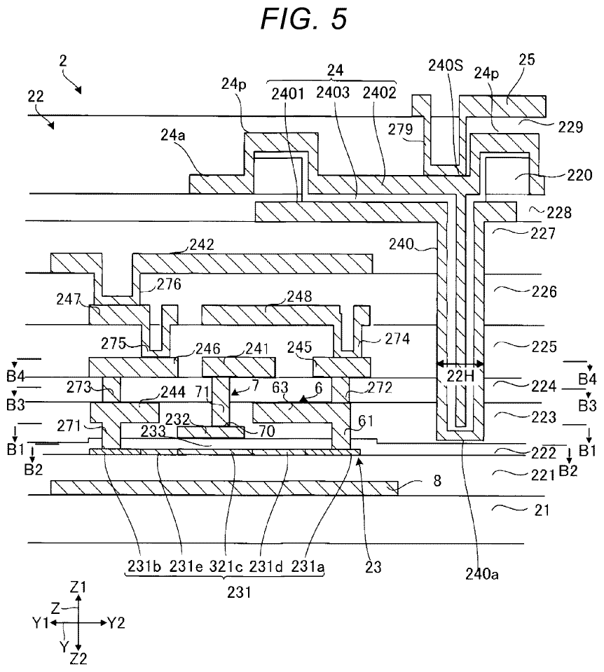

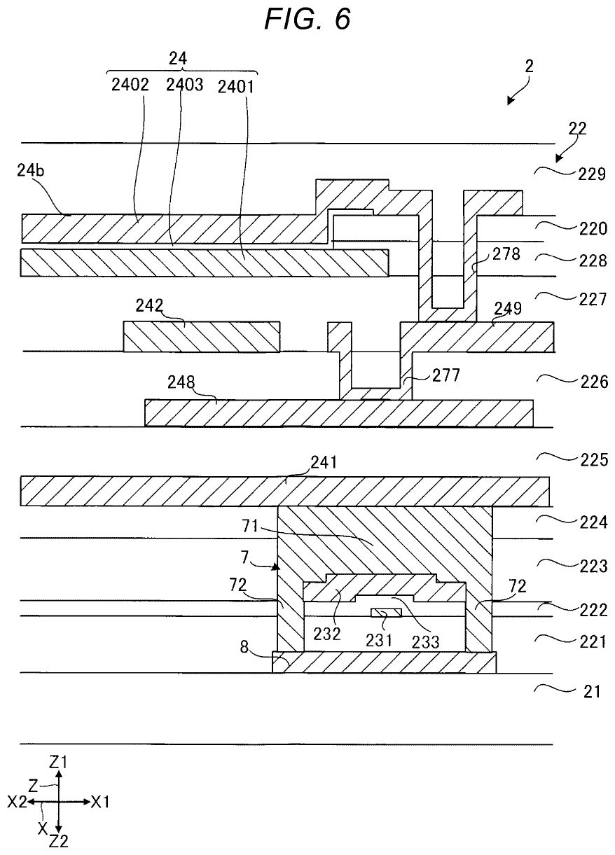

The element substrate 2 shown in FIG. 2 includes a light-transmissive first substrate 21, a light-transmissive laminate 22, light-transmissive multiple pixel electrodes 25, and a light-transmissive first orientation film 29. The first substrate 21, the laminate 22, the multiple pixel electrodes 25, and the first orientation film 29 are layered on each other in this order in the Z1 direction. Note that the term “light transmissive” means transmitting part of visible light, and preferably means that the transmittance for visible light is 50% or higher. As will be described later in detail, the element substrate 2 includes light-blocking first light blockers 6, light-blocking second light blockers 7, and light-blocking third light blockers 8 shown in FIGS. 5 and 6. Note that the term “light blocking” means blocking part of visible light, and preferably means that the transmittance for visible light is lower than 50%, more preferably, 10% or lower.

The first substrate 21 shown in FIG. 2 corresponds to a “substrate”. The first substrate 21 is a light-transmissive, insulating planar plate, and is configured, for example, with a glass substrate or a quartz substrate. The laminate 22 includes multiple light-transmissive insulating films. The laminate 22 is provided with various types of wiring and the like. The pixel electrodes 25 are each used to apply an electric field to the liquid crystal layer 5. The pixel electrodes 25 contain, for example, a transparent, electrically conductive material such as indium tin oxide (ITO), indium zinc oxide (IZO), and fluorine-doped tin oxide (FTO). Note that the element substrate 2 includes, although not shown, multiple dummy pixel electrodes that surround the multiple pixel electrodes 25 in the plan view. The first orientation film 29 is a light-transmissive, insulating film. The first orientation film 29 orients the liquid crystal molecules of the liquid crystal layer 5 in a specific direction. The first orientation film 29 is disposed so as to cover the multiple pixel electrodes 25. The material of the first orientation film 29 is, for example, polyimide or silicon oxide.

The counter substrate 3 is disposed so as to face the element substrate 2. The counter substrate 3 includes a light-transmissive second substrate 31, a light-transmissive inorganic insulating layer 32, a light-transmissive common electrode 33, and a light-transmissive second orientation film 34. Although not shown, the counter substrate 3 includes a light-blocking partition that surrounds the multiple pixel electrodes 25 in the plan view.

The second 31, substrate the inorganic insulating layer 32, the common electrode 33, and the second orientation film 34 are layered on each other in this order in the Z2 direction. The second substrate 31 is a light-transmissive, insulating planar plate, and is configured, for example, with a glass substrate or a quartz substrate. The inorganic insulating layer 32 is a light-transmissive, insulating layer, and is made, for example, of an inorganic material containing silicon such as silicon oxide. The common electrode 33 is a counter electrode disposed so as to face the multiple pixel electrodes 25 via the liquid crystal layer 5. The common electrode 33 is used to apply electric fields to the liquid crystal layer 5. The common electrode 33 is a light-transmissive, electrically conductive electrode. The common electrode 33 contains, for example, a transparent, electrically conductive material such as ITO, IZO, and FTO. The second orientation film 34 is a light-transmissive, insulating film. The second orientation film 34 orients the liquid crystal molecules of the liquid crystal layer 5 in a specific direction. The material of the second orientation film 34 is, for example, polyimide or silicon oxide.

The sealing member 4 is disposed between the element substrate 2 and the counter substrate 3. The sealing member 4 is formed, for example, by using an adhesive containing any of various curable resins such as an epoxy resin. The sealing member 4 may include a gap member made of an inorganic material such as glass.

The liquid crystal layer 5 is disposed in the region surrounded by the element substrate 2, the counter substrate 3, and the sealing member 4. The liquid crystal layer 5 is an electro-optical layer having an optical characteristic that changes in accordance with the electric field. The liquid crystal layer 5 contains liquid crystal molecules having positive or negative dielectric anisotropy. The orientation of the liquid crystal molecules changes in accordance with a voltage applied to the liquid crystal layer 5.

Multiple scan line driving circuits 11, a signal line driving circuit 12, and multiple external terminals 13 are disposed at the element substrate 2, as shown in FIG. 1. Some of the multiple external terminals 13 are coupled to wiring that is not shown but is drawn from the scan line driving circuits 11 or the signal line driving circuit 12. The multiple external terminals 13 include a terminal to which a constant potential Vcom is applied. The terminal is electrically coupled to the common electrode 33 of the counter substrate 3 via wiring and a conductive member neither of which is shown. The constant potential Vcom is therefore supplied to the common electrode 33.

The thus configured electro-optical device 100 has a display region A10, which displays an image, and a peripheral region A20, which is located outside the display region A10 in the plan view. The display region A10 is provided with multiple pixels P arranged in a matrix. The multiple pixel electrodes 25 are arranged in correspondence with the multiple pixels P in a one-to-one relationship. The common electrode 33 described above is provided so as to be common to the multiple pixels P. The peripheral region A20 surrounds the display region A10 in the plan view. The scan line driving circuits 11 and the signal line driving circuit 12 are disposed in the peripheral region A20.

In the present embodiment, the electro-optical device 100 is a transmissive device. Specifically, an image is displayed when light LL enters the counter substrate 3 and is then modulated before exiting out of the element substrate 2, as shown in FIG. 2. Note that an image may be displayed when light having entered the element substrate 2 is modulated before exiting out of the counter substrate 3.

The electro-optical device 100 is used, for example, in a display apparatus that performs display operation in color, such as a personal computer and a smartphone, which will be described later. When used in the display apparatus, the electro-optical device 100 uses a color filter as appropriate. The electro-optical device 100 is also used, for example, in a projection-type projector that will be described later. In this case, the electro-optical device 100 functions as a light valve. Note in this case that the color filter is omitted from the electro-optical device 100.

### 1B. Electrical Configuration of Element Substrate 2

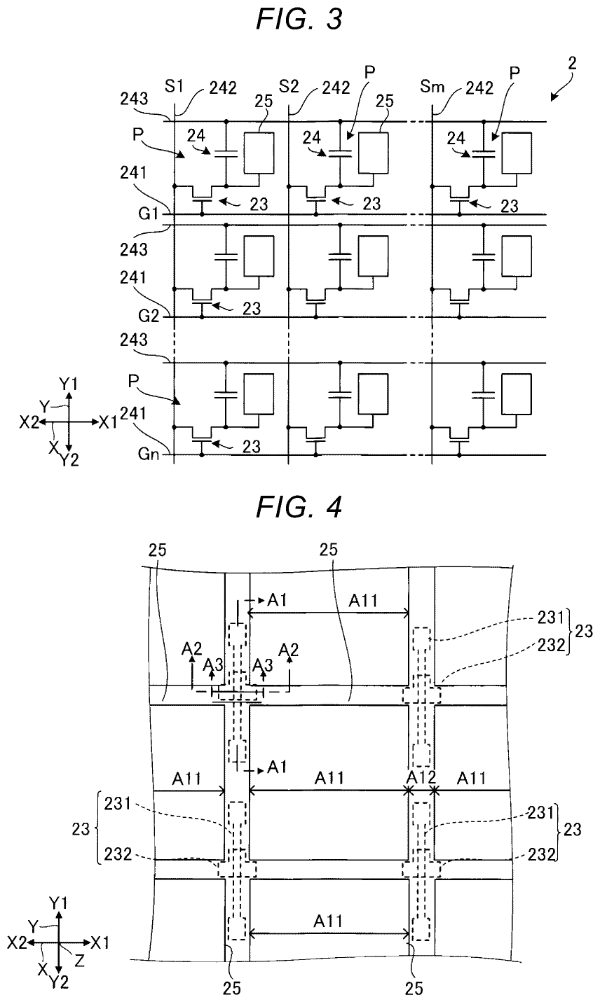

FIG. 3 is an equivalent circuit diagram showing the electrical configuration of the element substrate 2 in FIG. 1. The element substrate 2 includes multiple transistors 23, n scan lines 241, m signal lines 242, and n constant potential lines 243, as shown in FIG. 3. Each of n and m is an integer greater than or equal to two. The transistors 23 are disposed in correspondence with the intersections of the n scan lines 241 and the m signal lines 242. The transistors 23 are each, for example, a thin film transistor (TFT) that functions as a switching element. The transistors 23 each include a gate, a source, and a drain.

The n scan lines 241 extend in the X1 direction, and are arranged at equal intervals in the Y1 direction. The n scan lines 241 are each electrically coupled to the gate of the corresponding one of the multiple transistors 23. The n scan lines 241 are electrically coupled to the scan line driving circuits 11 shown in FIG. 1. Scan signals G1, G2, . . . , and Gn are supplied in a line sequential manner from the scan line driving circuits 11 to the first to n-th scan lines 241.

The m signal lines 242 shown in FIG. 3 extend in the Y1 direction, and are arranged at equal intervals in the X1 direction. The m signal lines 242 are each electrically coupled to the source of the corresponding one of the multiple transistors 23. The m signal lines 242 are electrically coupled to the signal line driving circuit 12 shown in FIG. 1. Image signals S1, S2, . . . , and Sm are supplied in parallel from the signal line driving circuit 12 to the first to m-th signal lines 242.

The n scan lines 241 and the m signal lines 242 shown in FIG. 3 are electrically insulated from each other and arranged in a lattice in the plan view. A region surrounded by two adjacent scan lines 241 and two adjacent signal lines 242 corresponds to a pixel P. A transistor 23, a pixel electrode 25, and a capacitance element 24 are provided for each of the pixels P. The pixel electrodes 25 are provided in correspondence with the transistors 23 in a one-to-one relationship. The pixel electrodes 25 are each electrically coupled to the drain of the corresponding transistor 23.

The n constant potential lines 243 extend in the X1 direction, and are arranged at equal intervals in the Y2 direction. The n constant potential lines 243 are electrically insulated from the n scan lines 241 and the m signal lines 242, and arranged at intervals with respect to the scan lines 241 and the signal lines 242. The constant potential Vcom is applied to each of the constant potential lines 243. The n constant potential lines 243 are each electrically coupled to one of two electrodes of the corresponding capacitance element 24. The capacitance elements 24 are each a capacitance element that holds the potential of the corresponding pixel electrode 25. The capacitance elements 24 are provided in correspondence with the transistors 23 in a one-to-one relationship. The other of the two electrodes of each of the capacitance elements 24 is electrically coupled to the corresponding pixel electrode 25. Therefore, the constant potential Vcom is applied to the one electrode of each of the capacitance elements 24, and the other electrode of the capacitance element 24 is electrically coupled to the drain of the corresponding transistor 23.

When the scan signals G1, G2, . . . and Gn sequentially become active and the n scan lines 241 are sequentially selected, the transistors 23 coupled to the selected scan lines 241 are turned on. The image signals S1, S2, . . . , and Sm having magnitudes according to grayscales to be displayed are then captured into the pixels P corresponding to the selected scan lines 241 via the m signal lines 242, and are applied to the pixel electrodes 25. Voltages according to the grayscales to be displayed are thus applied to liquid crystal capacitance formed between the pixel electrodes 25 and the common electrode 33 in FIG. 2, so that the orientation of the liquid crystal molecules changes in accordance with the applied voltages. The applied voltages are held by the capacitance elements 24. Light is modulated by the change in the orientation of the liquid crystal molecules to allow display operation in gradation.

### 1C. Structure of Element Substrate 2

FIG. 4 shows a portion of the element substrate 2 in the display region A10 in FIG. 2. The display region A10 includes multiple opening regions A11 and a light blocking region A12, as shown in FIG. 4. The multiple opening regions A11 are arranged in a matrix in the plan view. The light blocking region A12 in the plan view has a frame-like shape located between the multiple opening regions A11. The opening regions A11 are each a region in which the corresponding pixel electrode 25 is disposed and through which light passes. The transistors 23 are disposed in the light blocking region A12. Although not shown in FIG. 4, various types of wiring such as the scan lines 241, the signal lines 242, and the constant potential lines 243 shown in FIG. 3, and the capacitance elements 24 are disposed in the light blocking region A12.

FIG. 5 is a cross-sectional view taken along the line A1-A1 in FIG. 4. FIG. 6 is a cross-sectional view taken along the line A2-A2 in FIG. 4. Note that a left portion of FIG. 5 is not the cross section taken along the line A1-A1, but shows a cross section of a trench portion 240 of each of the capacitance elements 24, which will be described later.

The element substrate 2 includes the first substrate 21, which is the “substrate”, and the laminate 22, as shown in FIGS. 5 and 6. The laminate 22 is disposed between the first substrate 21 and the pixel electrodes 25. The laminate 22 includes multiple insulating layers 221, 222, 223, 224, 225, 226, 227, 228, 229, and 220. The insulating layers 221, 222, 223, 224, 225, 226, 227, 228, and 229 are layered on each other in this order from the side facing the first substrate 21. The insulating layer 220 is disposed between the insulating layer 228 and the insulating layer 229. The insulating layers 221 to 220 are each a light transmissive, insulating layer. The material of each of the insulating layers 221 to 220 is, for example, an inorganic material containing silicon such as silicon oxide and silicon oxynitride.

The transistors 23, the multiple types of wiring, the first light blockers 6, the second light blockers 7, and the third light blockers 8 are disposed in the laminate 22. The multiple types of wiring are specifically the scan lines 241, the signal lines 242, and relay electrodes 244, 245, 246, 247, 248, and 249.

The first substrate 21 is configured, for example, with a glass substrate or a quartz substrate, as described above. The third light blockers 8 as a “light blocking film” are disposed between the first substrate 21 and the laminate 22. The third light blockers 8 are provided to prevent entry of light into semiconductor layers 231 of the transistors 23. The third light blockers 8 overlap with the transistors 23 in the plan view. Specifically, the third light blockers 8 overlap with the semiconductor layers 231 of the transistors 23 in the plan view. The third light blockers 8 each have an elongated shape along the Y-axis, which is the direction in which the semiconductor layers 231 of the transistors 23 extend. Note that the first substrate 21 may have recesses that open in the Z1 direction. In this case, the third light blockers 8 may be disposed in the recesses.

The transistors 23 are disposed on the insulating layer 221. The transistors 23 each include the semiconductor layer 231, a gate electrode 232, and a gate insulating film 233. The semiconductor layer 231 is disposed on the insulating layer 221. The gate electrode 232 is disposed on the insulating layer 222. The gate insulating film 233 is interposed between the gate electrode 232 and the semiconductor layer 231. A region of the insulating layer 222 corresponding to the gate electrode 232 in the plan view corresponds to the gate insulating film 233.

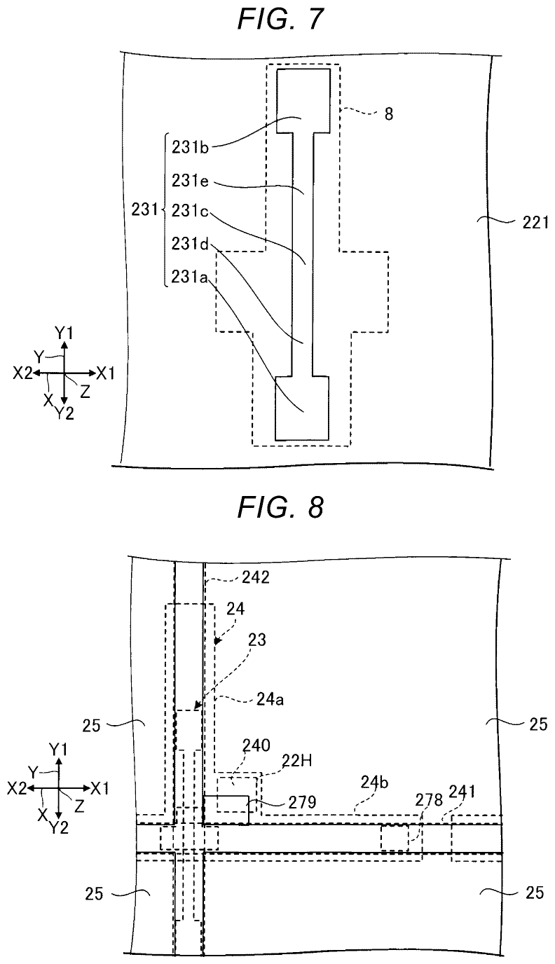

FIG. 7 is a plan view of the transistor 23 in FIG. 5. The transistor 23 shown in FIGS. 5 and 7 has a lightly doped drain (LDD) structure. The semiconductor layer 231 extends in the Y1 direction in the plan view. The semiconductor layer 231 has a drain region 231a, a source region 231b, a channel region 231c, a low-concentration drain region 231d, and a low-concentration source region 231e. The channel region 231c is located between the drain region 231a and the source region 231b. The low-concentration drain region 231d is located between the channel region 231c and the drain region 231a. The low-concentration source region 231e is located between the channel region 231c and the source region 231b. The semiconductor layer 231 is made, for example, of polysilicon. The region excluding the channel region 231c is doped with an impurity that increases electrical conductivity. The impurity concentration in the low-concentration drain region 231d is lower than the impurity concentration in the drain region 231a. The impurity concentration in the low-concentration source region 231e is lower than the impurity concentration in the source region 231b. Note, for example, that the transistor 23 may not have the LDD structure, so that the low-concentration source region 231e and the low-concentration drain region 231d may be omitted. The semiconductor layer 231 overlaps with the third light blocker 8 in the plan view.

The gate electrode 232 is formed, for example, by doping polysilicon with an impurity that increases electrical conductivity. Note that the gate electrode 232 may be made of an electrically conductive material such as a metal, a metal oxide, and a metal compound. The gate electrode 232 overlaps with the channel region 231c of the semiconductor layer 231 in the plan view. The gate insulating film 233 is configured, for example, with a silicon oxide film deposited by thermal oxidation, chemical vapor deposition (CVD), or the like.

The first light blocker 6 and the second light blocker 7 are disposed above and alongside the transistor 23, as shown in FIGS. 5 and 6. The first light blocker 6 and the second light blocker 7 are each configured, for example, with a laminate configured with multiple layers. The first light blocker 6 and the second light blocker 7 are each formed, for example, by using a damascene method. The first light blocker 6 is electrically coupled to the drain region 231a of the semiconductor layer 231. The second light blocker 7 is electrically coupled to the gate electrode 232. The second light blocker 7 is directly coupled to the third light blocker 8, and the second light blocker 7 is electrically coupled to the third light blocker 8, as shown in FIG. 6. The third light blocker 8 functions as a back gate. Providing the first light blocker 6, the second light blocker 7, and the third light blocker 8 can suppress entry of light into the low-concentration drain region 231d of the semiconductor layer 231.

The relay electrode 244 is disposed in the insulating layer 223, as shown in FIG. 5. The relay electrode 244 is electrically coupled to the source region 231b of the semiconductor layer 231 via a contact 271. For example, the contact 271 is a contact plug that fills a hole passing through the insulating layers 222 and 223. Note that the relay electrode 244 and the contact 271 are made of the same material and integrated with each other, but may instead be made of different materials.

The scan line 241, the relay electrode 245, and the relay electrode 246 are disposed on the insulating layer 224, as shown in FIG. 5. The scan line 241 is electrically coupled to the gate electrode 232 via the second light blocker 7. The relay electrode 245 is electrically coupled to the first light blocker 6 via a contact 272 passing through the insulating layer 224. The relay electrode 246 is electrically coupled to the relay electrode 244 via a contact 273 passing through the insulating layer 224. Note that the contacts 272 and 273 are each, for example, a contact plug that fills a hole passing through the insulating layer 224.

The relay electrode 247 and the relay electrode 248 are disposed on the insulating layer 225. The relay electrode 247 is electrically coupled to the relay electrode 246 via a contact 275 passing through the insulating layer 225. Note that the contact 275 has, for example, a trench structure integrated with the relay electrode 247 and provided along the inner wall surface of a hole formed in the insulating layer 225. The relay electrode 248 is electrically coupled to the relay electrode 245 via a contact 274 passing through the insulating layer 225. Note that the contact 274 is integrated with the relay electrode 248 and has a trench structure provided along the inner wall surface of a hole formed in the insulating layer 225.

The signal line 242 is disposed on the insulating layer 226. The signal line 242 is electrically coupled to the relay electrode 247 via a contact 276 passing through the insulating layer 226. The signal line 242 is therefore electrically coupled to the source region 231b via the contact 276, the relay electrode 247, the contact 275, the relay electrode 246, the contact 273, the relay electrode 244, and the contact 271. Note that the contact 276 has a trench structure integrated with the signal line 242 and provided along the inner wall surface of a hole formed in the insulating layer 226.

The relay electrode 249 is disposed on the insulating layer 226, as shown in FIG. 6. The relay electrode 249 is electrically coupled to the relay electrode 248 via a contact 277 passing through the insulating layer 226. Note that the contact 277 has a trench structure integrated with the relay electrode 249 and provided along the inner wall surface of a hole formed in the insulating layer 226.

The capacitance element 24 is disposed on the insulating layer 227. The capacitance element 24 is primarily disposed between the transistor 23 and the pixel electrode 25 in the laminate 22. The capacitance element 24 includes a first capacitance electrode 2401, a dielectric 2403, and a second capacitance electrode 2402. The first capacitance electrode 2401 is disposed on the insulating layer 227. The second capacitance electrode 2402 is disposed on the insulating layer 228. The dielectric 2403 is disposed between the first capacitance electrode 2401 and the second capacitance electrode 2402. The first capacitance electrode 2401 also serves as the constant potential line 243 in FIG. 3. The second capacitance electrode 2402 is electrically coupled to the relay electrode 249 via a contact 278 passing through the insulating layers 227 and 228. The second capacitance electrode 2402 is therefore electrically coupled to the drain region 231a via the contact 278, the relay electrode 249, the contact 277, the relay electrode 248, the contact 274, the relay electrode 245, the contact 272, and the first light blocker 6, as shown in FIG. 5 or 6. Note that the contact 278 has a trench structure integrated with the second capacitance electrode 2402 and provided along the inner wall surface of a hole formed in the insulating layers 227 and 228.

The pixel electrode 25 is disposed on the insulating layer 229, as shown in FIG. 5. The pixel electrode 25 is electrically coupled to the second capacitance electrode 2402 via a pixel electrode contact 279 passing through the insulating layer 229. The pixel electrode contact 279 is directly coupled to the second capacitance electrode 2402. Note that the pixel electrode contact 279 has a trench structure integrated with the pixel electrode 25 and provided along the inner wall surface of a hole formed in the insulating layer 229. The pixel electrode contact 279 is therefore directly coupled to the pixel electrodes 25.

The scan line 241, the signal line 242, the first capacitance electrode 2401, the second capacitance electrode 2402, and the relay electrodes 244, 245, 246, 247, 248, and 249 described above each contain, for example, metal such as tungsten (W), titanium (Ti), chromium (Cr), iron (Fe), and aluminum (Al); metal nitride; and metal silicide. The elements described above may each be a monolayer or a laminate. For example, the elements described above are each configured with a laminate of an aluminum film and a titanium nitride film.

The contacts 271 to 278 and the pixel electrode contact 279 described above each contain, for example, a metal such as tungsten (W), titanium (Ti), chromium (Cr), iron (Fe), and aluminum (Al); metal nitride; and metal silicide. The contacts 271 to 278 and the pixel electrode contact 279 may each be a monolayer or a laminate. The contacts 271 to 278 and the pixel electrode contact 279 may each be integrated with or may be formed separately from the electrode or the wiring to be coupled thereto. The contacts 271 to 278 and the pixel electrode contact 279 may each have a trench structure or may be a contact plug.

Note that the configuration of the element substrate 2 shown in FIGS. 5 and 6 is an example. For example, the element substrate 2 may include a capacitance element different from the capacitance element 24. The scan line 241, the signal line 242, and the capacitance element 24 are arranged in this order in the Z1 direction, but are not necessarily arranged in this order.

### 1D. Capacitance Element 24

The laminate 22 is provided with a hole portion 22H, as shown in FIG. 5. The hole portion 22H is a hole passing through the insulating layers 223 to 228, and has a bottom portion located in the insulating layer 223. The bottom portion is located below the gate electrode 232.

The capacitance element 24 has the trench portion 240. The trench portion 240 is a portion of the capacitance element 24 that is the portion provided in the hole portion 22H. The trench portion 240 has a trench structure formed along the inner wall surface that forms the hole portion 22H of the capacitance element 24, and is a plug-shaped element that fills the hole portion 22H. The trench portion 240 is configured with a portion of the first capacitance electrode 2401, a portion of the second capacitance electrode 2402, and a portion of the dielectric 2403. The trench portion 240 is also a portion of the capacitance element 24 that is a portion extending in the laminating direction of the laminate 22.

FIG. 8 shows a planar arrangement of the trench portion 240 and the pixel electrode 25 shown in FIG. 5.

The pixel electrode contact 279 is provided at a corner of the pixel electrode 25 in the plan view, as shown in FIG. 8. The pixel electrode 25 has a substantially quadrangular shape in the plan view, and the pixel electrode contact 279 is provided at one of the four corners of the pixel electrode 25.

The trench portion 240 overlaps with the pixel electrode contact 279 in the plan view. The trench portion 240 is therefore regarded as being located in the opening region A11. When the pixel electrode contact 279 is a contact plug, the trench portion 240 overlaps with the pixel electrode 25 in the plan view. When the pixel electrode contact 279 has a trench structure, the pixel electrode contact 279 is integrated with the pixel electrode 25, so that the pixel electrode contact 279 is also regarded as a portion of the pixel electrode 25. In this case, the trench portion 240 is also regarded as overlapping with the pixel electrode 25 in the plan view. Note that when the pixel electrode contact 279 has a trench structure, the trench structure is not a plug-shaped structure but is a structure provided along the inner wall surface of a contact hole in the insulating layer 229. In contrast, the trench portion 240 is a plug-shaped portion that fills the hole portion 22H.

Since the trench portion 240 overlaps with the pixel electrode contact 279 in the plan view, the aspect ratio of the trench portion 240 can be readily increased even when the frame-shaped light blocking region A12 is reduced to increase the opening ratio. That is, since the trench portion 240 overlaps with the pixel electrode contact 279, the aspect ratio of the trench portion 240 is readily increased even when the opening ratio is increased, as compared with a case where the trench portion 240 overlaps with the transistor 23 or the various types of wiring in the plan view. Therefore, even when the opening ratio is increased, the capacitance of the capacitance element 24 can be increased. In the example shown in FIG. 8, the hole portion 22H and the trench portion 240 overlap with a portion of the pixel electrode contact 279, and are located closer to the center of the opening region A11 than the pixel electrode contact 279 in the plan view.

The trench portion 240 is provided at a location different from the location where the transistor 23 is provided in the plan view. That is, the trench portion 240 does not overlap with the transistor 23 in the plan view. A bottom portion 240a of the trench portion 240 can therefore be provided so as to be at the same level as and even below the transistor 23, as shown in FIG. 5. Therefore, even when the opening ratio is increased, the capacitance of the capacitance element 24 can be increased. Note that in the example shown in FIG. 5, the bottom portion 240a is located in a layer between the gate electrode 232 and the semiconductor layer 231, and may instead be located in a layer below the semiconductor layer 231.

The multiple types of wiring are provided in the laminate 22, as described above. The multiple types of wiring are provided in the light blocking region A12. Although no detailed plan view is shown, the trench portion 240 is provided at a location different from the locations where the multiple types of wiring are provided in the plan view. That is, the trench portion 240 does not overlap with the multiple types of wiring in the plan view. Examples of the multiple types of wiring may include the scan line 241, the signal line 242, and the relay electrodes 244, 245, 246, 247, 248, and 249.

Since the trench portion 240 does not overlap with the multiple types of wiring in the plan view, the bottom portion 240a of the trench portion 240 can be provided so as to be at the same level as and even below the various types of wiring. Therefore, even when the opening ratio is increased, the capacitance of the capacitance element 24 can be increased.

The signal line 242 and the scan line 241 as a specific example of the multiple types of wiring are provided between the transistor 23 and the pixel electrode 25 in the laminate 22. The trench portion 240 is provided at a location different from the locations where the signal line 242 and the scan line 241 are provided in the plan view. That is, the trench portion 240 does not overlap with the signal line 242 or the scan line 241 in the plan view. The bottom portion 240a of the trench portion 240 can be provided so as to be at the same level as and even below the signal line 242 and the scan line 241. Therefore, even when the opening ratio is increased, the capacitance of the capacitance element 24 can be increased. The trench portion 240 extends from a position above the signal line 242 and the scan line 241 to a position below the gate electrode 232. The capacitance of the capacitance element 24 can therefore be significantly increased.

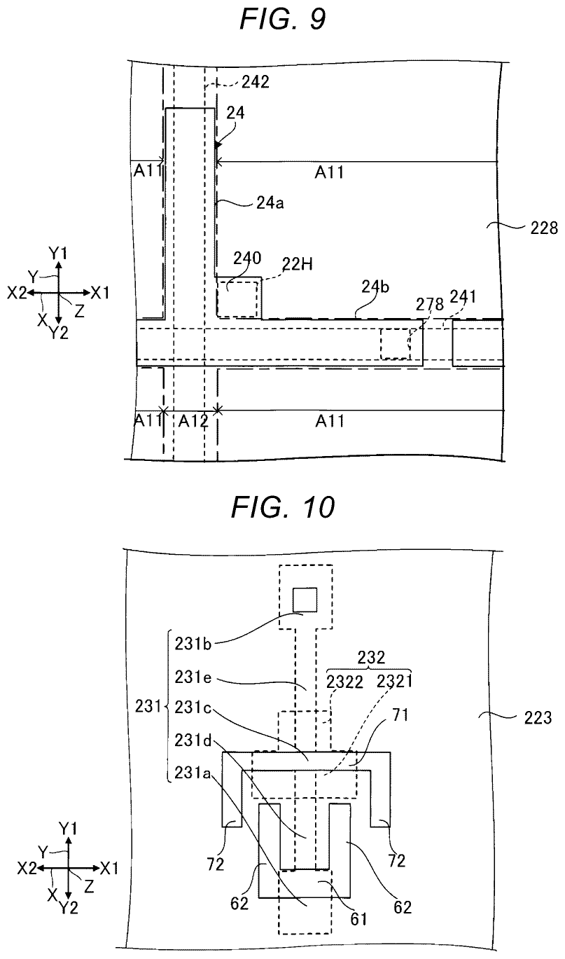

FIG. 9 shows a planar arrangement of the capacitance element 24 shown in FIG. 5. The capacitance element 24 includes a first extension 24a and a second extension 24b, as shown in FIG. 9. The first extension 24a is a portion extending along the Y-axis, which is the direction in which the signal line 242 extends in the plan view. The second extension 24b is a portion extending along the direction in which the scan line 241 extends in the plan view. The trench portion 240 is provided in correspondence with the intersection of the first extension 24a and the second extension 24b.

Since the capacitance element 24 includes the first extension 24a and the second extension 24b, the capacitance can be increased as compared with a case where the capacitance element 24 does not include the two extensions. According to the thus configured capacitance element 24, the first extension 24a and the second extension 24b can increase the capacitance in the X-Y plane perpendicular to the Z-axis while the trench portion 240 increases the capacitance in the direction along the Z-axis.

The upper surface of the second capacitance electrode 2402, which forms the trench portion 240, is a planar surface 240S, as shown in FIG. 5. The planar surface 240S includes not only a completely planar surface but also a surface having no intentionally formed unevenness but having fine unevenness and surface roughness that can be produced when manufactured. The pixel electrode contact 279 is provided on the planar surface 240S. The pixel electrode contact 279 is in contact with the planar surface 240S. Note that the planar surface 240S is a portion of the second capacitance electrode 2402.

Since the thus configured planar surface 240S is present, the pixel electrode contact 279 is readily provided on the planar surface 240S. The pixel electrode contact 279 that overlaps with the trench portion 240 in the plan view is therefore readily realized.

The bottom portion 240a of the trench portion 240 is located between the gate electrode 232 and the third light blocker 8 as the “light blocking film”. Providing the bottom portion 240a at the position described above allows a significant increase in the capacitance of the capacitance element 24.

Note that the bottom portion 240a may be located below the third light blocker 8 from the viewpoint of increasing the capacitance. However, since the configuration in which the bottom portion 240a is located above the third light blocker 8 eliminates the need for providing the first substrate 21 with a recess in which a portion of the trench portion 240 is disposed, so that the trench portion 240 is readily manufactured as compared with a case where the recess is provided. The bottom portion 240a may be located above the gate electrode 232. However, the configuration in which the bottom portion 240a is located below the gate electrode 232 can increase the capacitance of the capacitance element 24 as compared with the configuration in which the bottom portion 240a is located above the gate electrode 232.

The first capacitance electrode 2401 is provided along the inner wall surface that forms the hole portion 22H and has a trench structure. In contrast, the second capacitance electrode 2402 is a plug-shaped electrode provided to fill the hole portion 22H. Since the second capacitance electrode 2402 is a plug-shaped electrode, the aspect ratio of the trench portion 240 is readily increased as compared with a case where the second capacitance electrode 2402 has a trench structure. An excessive increase in the planar area of the trench portion 240 can therefore be suppressed. Furthermore, since the second capacitance electrode 2402 is a plug-shaped electrode, the planar surface 240S described above is readily formed.

The first extension 24a of the capacitance element 24 includes a protrusion 24p, which protrudes in the Z1 direction beyond the other portions, as shown in FIG. 5. The first capacitance electrode 2401, the dielectric 2403, and the second capacitance electrode 2402 are layered on each other in a portion of the capacitance element 24 that is the portion other than the protrusion 24p. In contrast, in the protrusion 24p, the dielectric 2403 and the insulating layer 220 are disposed between the first capacitance electrode 2401 and the second capacitance electrode 2402.

### 1E. First Light Blocker 6 and Second Light Blocker 7

FIG. 10 is a plan view corresponding to the line B1-B1 in FIG. 5. The first light blocker 6 and the second light blocker 7 surround the low-concentration drain region 231d, which is a boundary portion between the drain region 231a and the channel region 231c, in the plan view, as shown in FIG. 10. That is, the first light blocker 6 and the second light blocker 7 are disposed around the low-concentration drain region 231d so as to confine the low-concentration drain region 231d in the region formed by the two light blockers in the plan view. The low-concentration drain region 231d is therefore disposed in the region formed by the first light blocker 6 and the second light blocker 7 in the plan view.

As described above, since the first light blocker 6 and the second light blocker 7 surround the low-concentration drain region 231d, entry of light into the low-concentration drain region 231d can be suppressed as compared with a case where the first light blocker 6 and the second light blocker 7 do not surround the low-concentration drain region 231d. In particular, entry of light sideways into the low-concentration drain region 231d can be suppressed. That is, the first light blocker 6 and the second light blocker 7 surround the low-concentration drain region 231d so as to suppress entry of light sideways into the low-concentration drain region 231d. Occurrence of operation failure or the like resulting from the photocurrent in the transistor 23 can therefore be more effectively suppressed than in the related art.

The first light blocker 6 is electrically coupled to the drain region 231a and therefore has the same potential as the drain region 231a, as described above. The second light blocker 7 is electrically coupled to the gate electrode 232 and therefore has the same potential as the gate electrode 232. According to the two light blockers, the first light blocker 6 electrically coupled to the drain region 231a and the second light blocker 7 electrically coupled to the gate electrode 232, a configuration in which the first light blocker 6 and the second light blocker 7 are closer to the low-concentration drain region 231d is more readily achieved than, for example, in a case where only the second light blocker 7 is provided. The entry of light into the low-concentration drain region 231d can therefore be effectively suppressed.

In the direction along the X-axis, the second light blocker 7 is disposed more outward from the low-concentration drain region 231d than the first light blocker 6, as shown in FIG. 10. Therefore, in the direction along the X-axis, the distance between the second light blocker 7 and the low-concentration drain region 231d is longer than the distance between the first light blocker 6 and the low-concentration drain region 231d. Since the second light blocker 7 is farther from the low-concentration drain region 231d than the first light blocker 6, the possibility of influence of the second light blocker 7, which has the gate potential, on the low-concentration drain region 231d is reduced. Specifically, an increase in off-state leakage current due to the situation in which the gate potential is present near the regions of the semiconductor layer 231 excluding the channel region 231c can be suppressed. Deterioration in display quality due, for example, to generation of black spots can therefore be suppressed. Note that the off-state leakage current is a leakage current that flows when the transistor 23 is turned off.

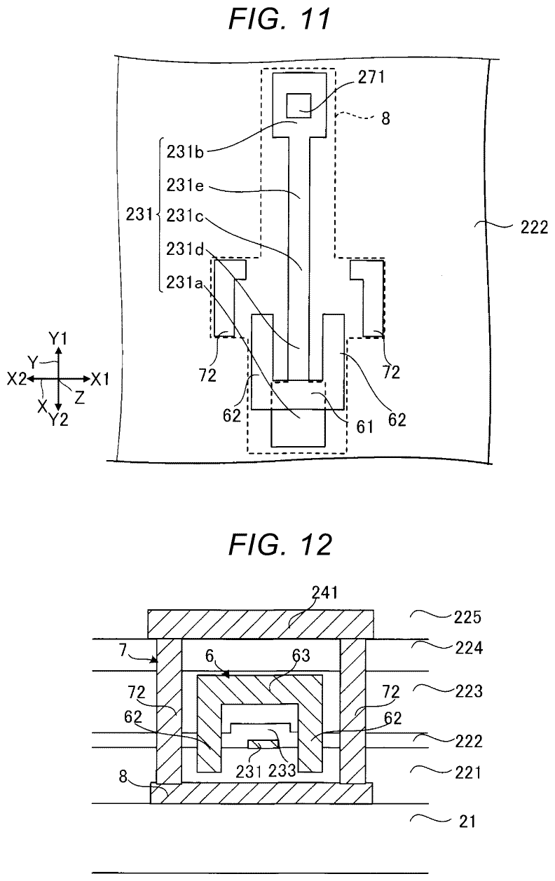

FIG. 11 is a plan view corresponding to the line B2-B2 in FIG. 5. FIG. 11 shows the first light blocker 6 and the second light blocker 7 being at the same level as the semiconductor layer 231.

The first light blocker 6 and the second light blocker 7 are disposed at the same level as the semiconductor layer 231 and sandwich the low-concentration drain region 231d, which is the boundary portion, as shown in FIG. 11. The first light blocker 6 and the second light blocker 7, which are disposed at the same level as the semiconductor layer 231, overlap with the entire low-concentration drain region 231d when viewed in the direction along the X-axis. The first light blocker 6 and the second light blocker 7 therefore cover the low-concentration drain region 231d when viewed in the direction along the X-axis. The first light blocker 6 and the second light blocker 7 can therefore reduce the possibility of entry of light into the low-concentration drain region 231d sideways from the region around the low-concentration drain region 231d.

In the present embodiment, the boundary portion between the drain region 231a and the channel region 231c corresponds to the low-concentration drain region 231d. The low-concentration drain region 231d is a region of the semiconductor layer 231 where light leakage is most likely to occur. Providing the first light blocker 6 and the second light blocker 7 so as to surround the low-concentration drain region 231d therefore allows in particular effective suppression of occurrence of operation failure or the like resulting from the photocurrent in the transistor 23.

Note that the transistor 23 has the low-concentration drain region 231d in the present embodiment, but the low-concentration drain region 231d may be omitted. For example, when the semiconductor layer 231 is configured with the drain region 231a, the source region 231b, and the channel region 231c, the first light blocker 6 and the second light blocker 7 are provided so as to surround the boundary portion between the drain region 231a and the channel region 231c.

FIG. 12 is a cross-sectional view taken along the line A3-A3 in FIG. 4. The first light blocker 6 and the second light blocker 7 each have a three-dimensional structure that covers the low-concentration drain region 231d, as shown in FIGS. 5, 6, and 12. The first light blocker 6 has a first portion 61, two second portions 62, and a fifth portion 63. The second light blocker 7 has a third portion 71 and two fourth portions 72.

The first portion 61 of the first light blocker 6 is disposed in the insulating layers 222 and 223, as shown in FIG. 5. The first portion 61 is a portion that overlaps with the drain region 231a in the plan view, as shown in FIGS. 10 and 11. The first portion 61 is coupled to the drain region 231a.

The two second portions 62 are each a portion extending from the first portion 61 in the Y1 direction in the plan view. The two second portions 62 are separate from each other and are disposed so as to sandwich the low-concentration drain region 231d, which is the boundary portion, from opposite sides in the direction along the X-axis, which is the width direction, in the plan view. The two second portions 62 are separate from the low-concentration drain region 231d, which is the boundary portion, in the plan view. The second portions 62 are each disposed in the insulating layers 221 to 223, as shown in FIG. 12. The second portions 62 are each disposed from a level above the semiconductor layer 231 to a level below the semiconductor layer 231. The lower end of each of the second portions 62 is located between the first substrate 21 and the insulating layer 222, in which the semiconductor layer 231 is provided.

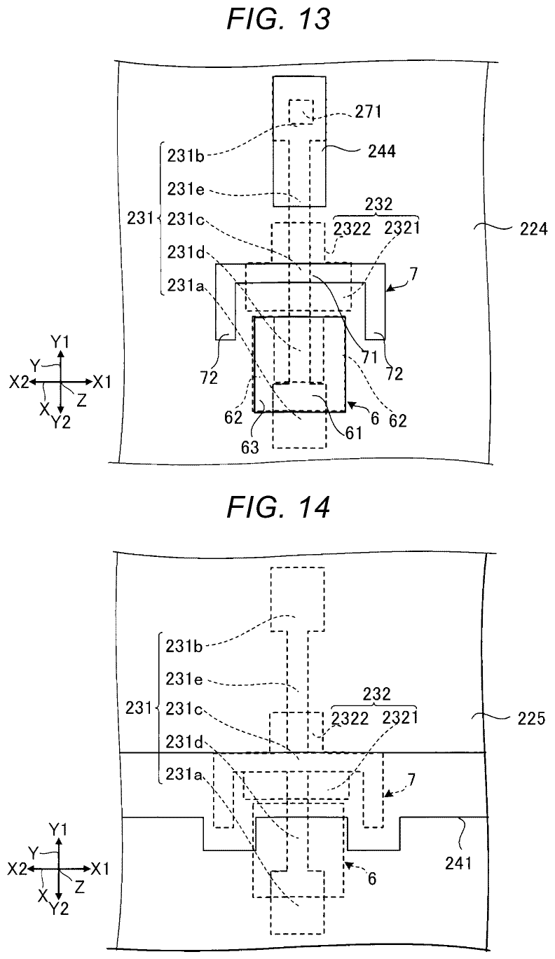

FIG. 13 is a plan view corresponding to the line B3-B3 in FIG. 5. The fifth portion 63 of the first light blocker 6 is coupled to the first portion 61 and the two second portions 62, and is disposed above the first portion 61 and the two second portions 62, as shown in FIGS. 5, 12, and 13. The fifth portion 63 overlaps with the first portion 61 and the two second portions 62 so as to cover these portions in the plan view. The fifth portion 63 overlaps with the low-concentration drain region 231d in the plan view.

The first light blocker 6 includes the fifth portion 63, which is a portion that overlaps with the low-concentration drain region 231d, which is the boundary portion, in the plan view. The first light blocker 6 can therefore reduce the possibility of entry of light into the low-concentration drain region 231d from above the low-concentration drain region 231d in addition to the entry of light sideways from the region around the low-concentration drain region 231d.

The third portion 71 of the second light blocker 7 is a portion located above the gate electrode 232, as shown in FIGS. 6 and 10. The third portion 71 is disposed in the insulating layers 223 and 224. The third portion 71 overlaps with the gate electrode 232 in the plan view. The third portion 71 extends along the X-axis. The third portion 71 is disposed in the insulating layers 223 and 224, as shown in FIG. 6. The third portion 71 is located between the two fourth portions 72.

The two fourth portions 72 each extend from the third portion 71 in the Y2 direction in the plan view, as shown in FIG. 13. Note that the fourth portions 72 each have a portion extending from the third portion 71 along the X-axis, as shown in FIG. 11. This portion is coupled to the portion extending in the Y2 direction. The two fourth portions 72 are separate from each other and are disposed so as to sandwich the low-concentration drain region 231d, which is the boundary portion, from opposite sides in the direction along the X-axis, which is the width direction, in the plan view. The two fourth portions 72 are separate from the low-concentration drain region 231d, which is the boundary portion, in the plan view. The two fourth portions 72 are located outside the two second portions 62 in the plan view. The fourth portions 72 are each disposed in the insulating layers 221 to 224, as shown in FIG. 12. The fourth portions 72 are each disposed from a level above the semiconductor layer 231 to a level below the semiconductor layer 231. The upper end of each of the fourth portions 72 is coupled to the scan line 241. The lower end of each of the fourth portions 72 is coupled to the third light blocker 8.

Since the second light blocker 7 having the third portion 71 and the two fourth portions 72 described above and the first light blocker 6 having the first portion 61 and the two second portions 62 described above are present, the first light blocker 6 and the second light blocker 7 can surround the low-concentration drain region 231d, as shown in FIG. 10.

The configuration in which the two fourth portions 72 are located outside the two second portions 62 in the plan view can suppress the possibility of influence of the fourth portions 72 having the gate potential on the low-concentration drain region 231d.

The two second portions 62 and the two fourth portions 72 overlap with the low-concentration drain region 231d when viewed in the direction along the X-axis. Furthermore, each of the two second portions 62 and each of the two fourth portions 72 overlap with each other in the direction along the X-axis, which is the width direction of the semiconductor layer 231. Entry of light sideways into the low-concentration drain region 231d can thus be effectively suppressed.

The two second portions 62 each have a linear shape along the Y1 direction, which is the direction in which the semiconductor layer 231 extends, in the plan view. The light blocking region A12, in which the first light blocker 6 is disposed, can therefore be reduced in size as compared with a case where the second portions 62 are each bent or curved. Therefore, the opening regions A11 can be enlarged, that is, the opening ratio can be improved.

Similarly, the two fourth portions 72 each have a linear shape along the Y1 direction, which is the direction in which the semiconductor layer 231 extends, in the plan view. The light blocking region A12, in which the second light blocker 7 is disposed, can therefore be reduced in size as compared with a case where the fourth portions 72 are each bent or curved. Therefore, the opening regions A11 can be enlarged, that is, the opening ratio can be improved.

A coupled portion 70, which is a portion of the second light blocker 7 that is coupled to the gate electrode 232, is located at a position on the gate electrode 232 that is shifted toward the drain region 231a in the plan view, as shown in FIG. 5. The thus disposed coupled portion 70 can reduce the size of the light blocking region A12, in which the second light blocker 7 is disposed. Therefore, the opening regions A11 can be enlarged, that is, the opening ratio can be improved.

The gate electrode 232 includes a first gate portion 2321 and a second gate portion 2322, as shown in FIG. 13. The second gate portion 2322 is located farther from the drain region 231a than the first gate portion 2321 in the plan view. The length of the second gate portion 2322 along the X-axis is smaller than the length of the first gate portion 2321 along the X-axis. The first gate portion 2321 is located at the intersection in the light blocking region A12. The second light blocker 7 is coupled to the first gate portion 2321.

The thus configured gate electrode 232 and the thus disposed second light blocker 7 can readily reduce the size of the light blocking region A12. Therefore, the opening regions A11 can be enlarged, that is, the opening ratio can be improved.

FIG. 14 is a plan view corresponding to the line B4-B4 in FIG. 5. The scan line 241 is located above the first light blocker 6 and overlaps with the first light blocker 6 in the plan view, as shown in FIG. 14. The scan line 241 in addition to the first light blocker 6 can therefore more effectively reduce the possibility of entry of light into the low-concentration drain region 231d from above the low-concentration drain region 231d.

No wiring or electrode is interposed between the first light blocker 6 and the low-concentration drain region 231d. The first light blocker 6 can therefore be very close to the low-concentration drain region 231d. The first light blocker 6 can therefore suppress entry of light traveling in the Z1 direction into the low-concentration drain region 231d.

The third light blocker 8 is disposed between the first substrate 21 and the semiconductor layer 231, as described above. The third light blocker 8 has the gate potential. The third light blocker 8 overlaps with the low-concentration drain region 231d in the plan view. Disposing the thus configured third light blocker 8 at a position below the semiconductor layer 231 can suppress entry of light from below the semiconductor layer 231 into the low-concentration drain region 231d. The first light blocker 6, the second light blocker 7, and the third light blocker 8 can thus effectively suppress omnidirectional entry of light into the low-concentration drain region 231d.

### 1F. Method for Manufacturing Capacitance Element 24

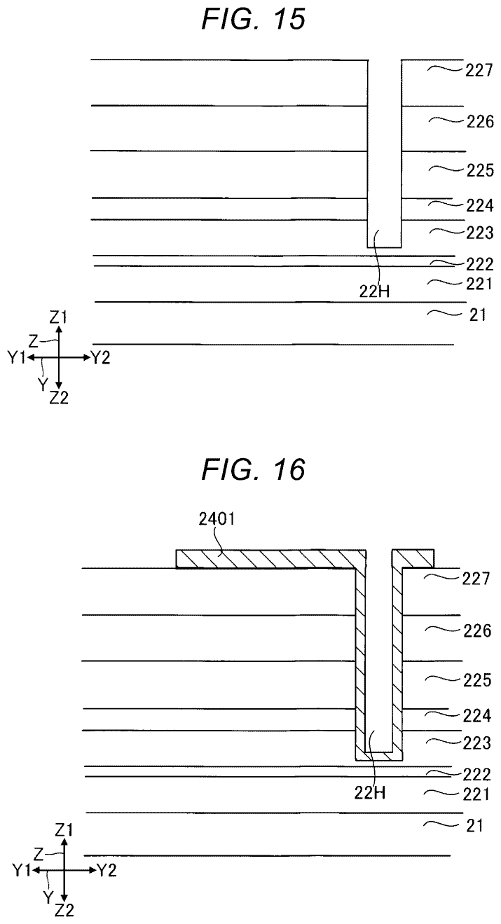

FIGS. 15, 16, 17, 18, 19, and 20 each show an example of a method for manufacturing the capacitance element 24. The hole portion 22H is first formed by etching so as to pass through the insulating layers 223 to 227, as shown in FIG. 15. The hole portion 22H opens through the upper side of the insulating layer 227 and has a bottom in the insulating layer 223.

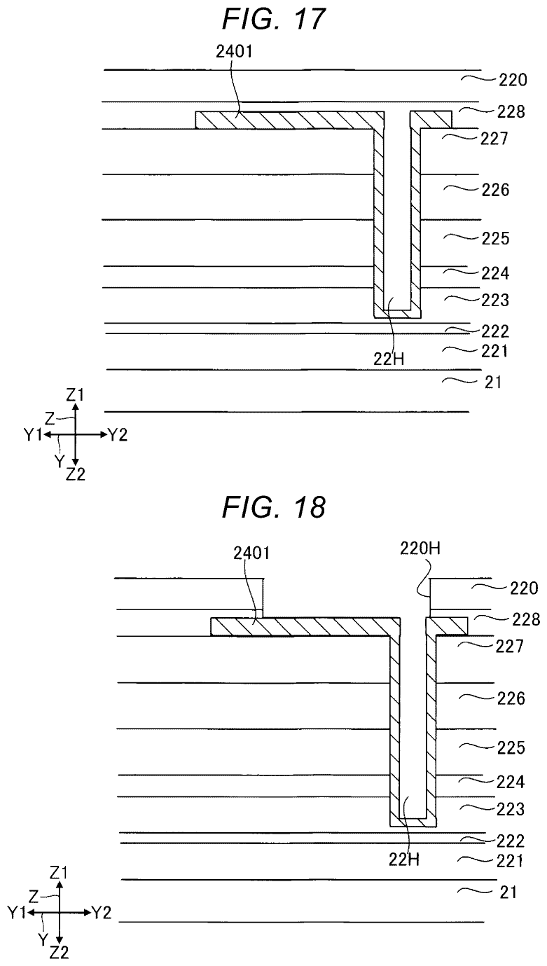

The first capacitance electrode 2401 is then deposited on the insulating layer 227, as shown in FIG. 16. For example, the first capacitance electrode 2401 is formed by depositing a film by using chemical vapor deposition (CVD) or sputtering and then patterning the film. In this process, a portion of the first capacitance electrode 2401 is formed along the inner wall surface that constitutes the hole portion 22H.

Thereafter, the insulating layer 228 is formed on the insulating layer 227 so as to cover the first capacitance electrode 2401, and the insulating layer 220 is then formed on the insulating layer 228, as shown in FIG. 17. The insulating layers 228 and 220 are deposited, for example, by using CVD or sputtering.

A hole 220H passing through the insulating layers 228 and 220 is then formed by etching to expose a portion of the first capacitance electrode 2401, as shown in FIG. 18. As a result, the hole 220H communicates with the hole portion 22H.

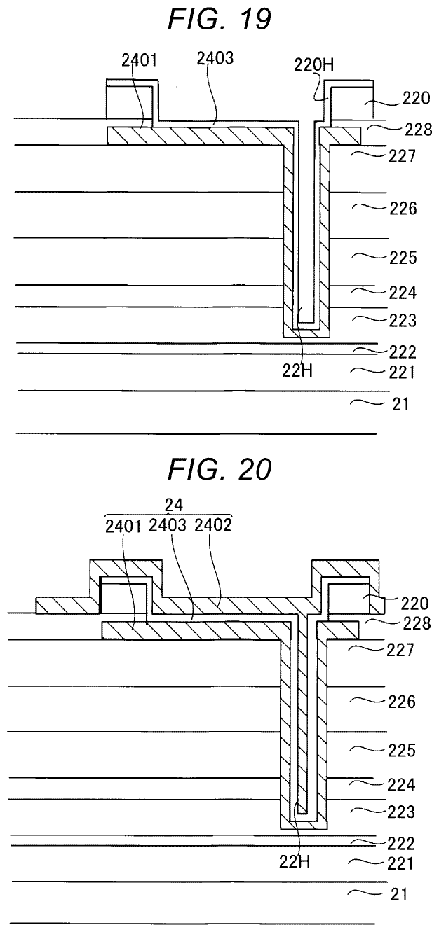

Thereafter, the dielectric 2403 is formed on the insulating layer 220, and the insulating layer 220 and the dielectric 2403 are then patterned by etching, as shown in FIG. 19. The dielectric 2403 is thus patterned into a shape corresponding to the first capacitance electrode 2401. In this process, a portion of the dielectric 2403 is formed on the first capacitance electrode 2401 along the inner wall surface of the hole portion 22H.

The second capacitance electrode 2402 is then deposited on the insulating layer 228, for example, by using CVD or sputtering so as to cover the dielectric 2403, as shown in FIG. 20. In this process, a portion of the second capacitance electrode 2402 is disposed in the hole portion 22H, which is formed by the dielectric 2403, so as to fill the hole portion 22H.

The capacitance element 24 including the trench portion 240 disposed in the hole portion 22H is formed as described above.

### 2. Variations

The embodiment presented above by way of example can be variously modified. Specific aspects of modifications applicable to the embodiment described above will be presented below by way of example. Two or more aspects freely selected from the examples presented below can be combined with each other as appropriate to the extent that no contradiction occurs.

In the embodiment described above, the electro-optical device 100 driven in the active matrix mode is presented by way of example, but the present disclosure is not limited thereto, and the electro-optical device 100 may be driven, for example, in a passive matrix mode.

The “electro-optical device” is not necessarily driven in a vertical electric field mode and may be driven in a horizontal electric field mode. Note that the horizontal electric field mode may, for example, be an in-plane switching (IPS) mode. Examples of the vertical electric field mode may include a twisted nematic (TN) mode, a vertical alignment (VA) mode, a PVA mode, and an optically compensated bend (OCB) mode.

In the above description, the second light blocker 7 is coupled to the third light blocker 8, but may not be coupled thereto. The third light blocker 8 may be omitted.

### 3. Electronic Instrument

The electro-optical device 100 can be used in various electronic instruments.

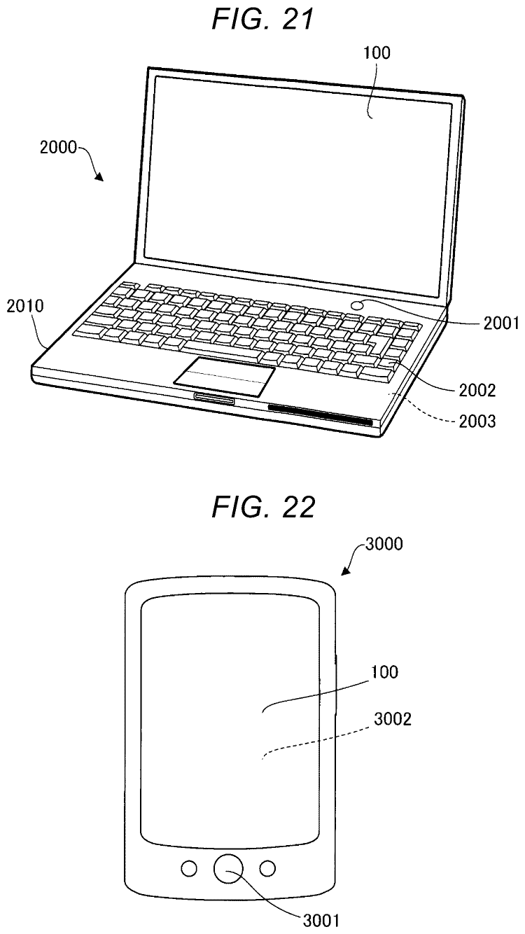

FIG. 21 is a perspective view showing a personal computer 2000 as an example of the electronic instrument. The personal computer 2000 includes the electro-optical device 100, which displays various images, a body 2010, which is provided with a power switch 2001 and a keyboard 2002, and a controller 2003. The controller 2003 includes, for example, a processor and a memory, and controls the operation of the electro-optical device 100.

FIG. 22 is a plan view showing a smartphone 3000 as an example of the electronic instrument. The smartphone 3000 includes an operation button 3001, the electro-optical device 100, which displays various images, and a controller 3002. The content displayed on the screen of the electro-optical device 100 is changed in accordance with the operation of the operation button 3001. The controller 3002 includes, for example, a processor and a memory, and controls the operation of the electro-optical device 100.

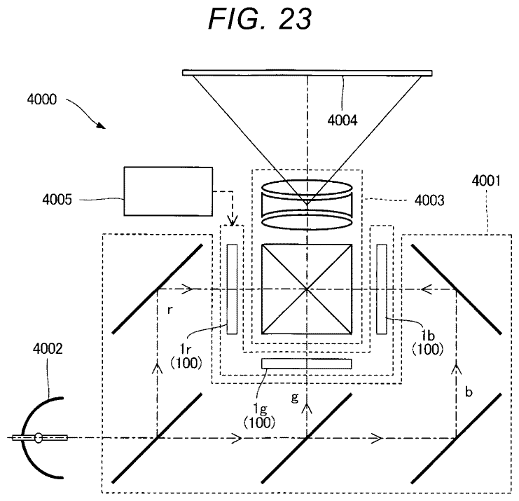

FIG. 23 is a diagrammatic view showing a projector as an example of the electronic instrument. A projection-type display apparatus 4000 is, for example, a three-plate projector. An electro-optical device 1r is the electro-optical device 100 corresponding to a red display color, an electro-optical device 1g is the electro-optical device 100 corresponding to a green display color, and an electro-optical device 1b is the electro-optical device 100 corresponding to a blue display color. That is, the projection-type display apparatus 4000 includes the three electro-optical devices 1r, 1g, and 1b corresponding to the red, green, and blue display colors, respectively. A controller 4005 includes, for example, a processor and a memory, and controls the operation of the electro-optical devices 100.

An illumination system 4001 supplies the electro-optical devices 1r, 1g, and 1b with a red component r, a green component g, and a blue component b of light output from an illuminator 4002, which is a light source. The electro-optical devices 1r, 1g, and 1b each function as a light modulator such as a light valve that modulates the corresponding monochromatic light supplied from the illumination system 4001 in accordance with an image to be displayed. A projection system 4003 combines the three types of light output from the electro-optical devices 1r, 1g, and 1b with one another and projects the combined light onto a projection receiving surface 4004.

The electronic instruments described above each include the electro-optical device 100 described above and the controller 2003, 3002, or 4005. In the electro-optical device 100 described above, it is expected that the capacitance element 24 increases the capacitance. The possibility of failure of display operation of the electro-optical device 100 is thus suppressed. Providing the electro-optical device 100 therefore allows an increase in the display quality of the personal computer 2000, the smartphone 3000, or the projection-type display apparatus 4000.

Note that the electronic instrument in which the electro-optical device according to the present disclosure is used is not limited to the instruments presented above by way of example, and may instead be a personal digital assistant (PDA), a digital still camera, a television, a video camcorder, a car navigation system, an in-vehicle display, an electronic organizer, electronic paper, an electronic calculator, a word processor, a workstation, a video phone, and a point of sale (POS) terminal. Furthermore, examples of the electronic instrument to which the present disclosure is applied may include a printer, a scanner, a copier, a video player, and an instrument including a touch panel.

The present disclosure has been described above based on the preferable embodiment, but the present disclosure is not limited to the embodiment described above. The configuration of each portion in the present disclosure may be replaced with any configuration that provides substantially the same function as in the embodiment described above, or any configuration may be added to the embodiment described.

In the above description, the liquid crystal display device has been described as an example of the electro-optical device according to the present disclosure, but the electro-optical device according to the present disclosure is not limited thereto. For example, the electro-optical device according to the present disclosure can also be used in an image sensor or the like.

What is claimed is:

1. An electro-optical device comprising:
a substrate;
a pixel electrode;
a laminate including multiple insulating layers disposed between the substrate and the pixel electrode;
a pixel electrode contact provided in the laminate and coupled to the pixel electrode;
a transistor provided in the laminate; and
a capacitance element provided in the laminate and including a first capacitance electrode, a dielectric, and a second capacitance electrode,
wherein the laminate is provided with a hole portion,
the capacitance element includes a trench portion provided in the hole portion, and
the trench portion overlaps with the pixel electrode contact in a plan view.

2. The electro-optical device according to claim 1, wherein
an upper surface of the second capacitance electrode that is a surface corresponding to the trench portion is a planar surface, and
the pixel electrode contact is provided on the planar surface.

3. The electro-optical device according to claim 1, wherein
the trench portion is provided at a location different from a location where the transistor is provided in the plan view.

4. The electro-optical device according to claim 1, wherein
the laminate is provided with multiple types of wiring, and
the trench portion is provided at a location different from a location where the multiple types of wiring are provided in the plan view.

5. The electro-optical device according to claim 1, wherein
a signal line and a scan line are provided between the transistor and the pixel electrode in the laminate, and
the trench portion is provided at a location different from a location where the signal line and the scan line are provided in the plan view.

6. The electro-optical device according to claim 5, wherein
the capacitance element includes a first extension extending along a direction in which the signal line extends in the plan view, and a second extension extending along a direction in which the scan line extends in the plan view.

7. The electro-optical device according to claim 1, further comprising
a light blocking film disposed between the substrate and the laminate and overlapping with the transistor in the plan view,
wherein the transistor includes a gate electrode, and
a bottom portion of the trench portion is located between the gate electrode and the light blocking film.

8. The electro-optical device according to claim 1, wherein
the first capacitance electrode is provided along an inner wall surface that forms the hole portion, and
the second capacitance electrode is provided so as to fill the hole portion.

9. The electro-optical device according to claim 1, wherein
the trench portion is a plug-shaped portion that fills the hole portion.

10. The electro-optical device according to claim 1, wherein
a signal line and a scan line are provided between the transistor and the pixel electrode in the laminate,
the transistor includes a gate electrode, and
the trench portion extends from a level above the signal line and the scan line to a level below the gate electrode.

11. An electronic instrument comprising:
the electro-optical device according to claim 1; and
a controller configured to control an operation of the electro-optical device.
